(19) United States
(12) Patent Application Publication
(10) Pub. No.: US 2007/0185679 A1
(43) Pub. Date: Aug. 9, 2007

(54) INDICATING STATUS OF A DIAGNOSTIC TEST SYSTEM

(76) Inventors: Patrick T. Petruno, San Jose, CA (US); Robert E. Wilson, Palo Alto, CA (US); Robert Yi, San Jose, CA (US)

Correspondence Address: Kathy Manke;Avago Technologies Limited, 4380 Ziegler Road, Fort Collins, CO, 80525, US

(21) Appl. No.: 11/567,156

(22) Filed: Dec. 5, 2006

Related U.S. Application Data
(63) Continuation-in-part of application No. 11/312,951, filed on Dec. 19, 2005.
Application No. 11/312,951 is a continuation-in-part of application No. 11/112,807, filed on Apr. 22, 2005.
Application No. 11/112,807 is a continuation-in-part of application No. 11/044,394, filed on Jan. 26, 2005.
Application No. 11/044,394 is a division of application No. 10/816,636, filed on Apr. 1, 2004.

(51) Int. Cl. G01R 27/28; G08B 1/08

(52) U.S. Cl. 702/117

(57) ABSTRACT

Systems and methods of indicating status of a diagnostic test system are described. In one aspect, a diagnostic test system includes a housing, an indicator system, and a test unit in the housing. The indicator system produces a non-textual sensory output signal that is perceptible from an area outside the housing. The test unit performs at least one diagnostic test on a diagnostic assay to determine whether at least one analyte is present within a sample. The test unit also produces a status indicator control signal triggering the indicator system to indicate a status of the diagnostic test via the non-textual sensory output signal.

### CROSS-REFERENCE TO RELATED APPLICATIONS

Under 35 U.S.C. § 120, this application claims the benefit of the following co-pending applications, each of which is incorporated herein by reference: U.S. patent application Ser. No. 10/816,636, filed Apr. 1, 2004, by Patrick T. Petruno et al., and entitled “Optoelectronic Rapid Diagnostic Test System;” U.S. patent application Ser. No. 11/044,394, filed Jan. 26, 2005, by Patrick T. Petruno et al., and entitled “Optoelectronic Rapid Diagnostic Test System;” U.S. patent application Ser. No. 11/112,807, filed Apr. 22, 2005, by Patrick T. Petruno et al., and entitled “Lateral Flow Assay Systems and Methods;” and U.S. patent application Ser. No. 11/312,951, filed Dec. 19, 2005, by Patrick T. Petruno, and entitled “Diagnostic Test Reader with Disabling Unit.”

### BACKGROUND

Patient samples often are analyzed for the presence of analytes to determine, for example, if a patient is carrying a disease, has an infection, or has been using drugs. Analytes typically are detected with immunoassay testing using antigen-antibody reactions. Conventionally, such tests have been carried out in specialized laboratories using diagnostic test systems that are large and expensive. The need for on-site examination, however, is growing rapidly. This need currently is being met by various point-of-care diagnostic test systems that can be used in a wide variety of different locations, such as hospitals, emergency rooms, health clinics, nursing homes, practitioner offices, and the homes of patients. The deployment of such point-of-care diagnostic test systems depends on the ability to keep costs below relatively low price points. In addition, point-of-care diagnostic test systems should be relatively easy to use by persons with little or no training. Ideally, such point-of-care diagnostic test systems should be capable of automatically performing diagnostic tests with minimal user input.

In many point-of-care environments, such as hospitals, emergency rooms, health clinics, nursing homes, and practitioner offices, a single user may run multiple point-of-care diagnostic tests concurrently. In order to improve the efficient use of the user's time, there is a need for the user to easily determine the status of each of the diagnostic tests.

### SUMMARY

In one aspect, the invention features a diagnostic test system that includes a housing, an indicator system, and a test unit in the housing. The indicator system produces a non-textual sensory output signal that is perceptible from an area outside the housing. The test unit performs at least one diagnostic test on a diagnostic assay to determine whether at least one analyte is present within a sample. The test unit also produces a status indicator control signal triggering the indicator system to indicate a status of the diagnostic test via the non-textual sensory output signal.

In another aspect, the invention features a diagnostic test method. In accordance with this method, within a housing at least one diagnostic test is performed on a diagnostic assay to determine whether at least one analyte is present within a sample. A non-textual sensory output signal that is perceptible from an area outside the housing is produced. The non-textual sensory output signal is indicative of a status of the diagnostic test.

Other features and advantages of the invention will become apparent from the following description, including the drawings and the claims.

### DESCRIPTION OF DRAWINGS

FIG. 1 is a block diagram of an embodiment of a diagnostic test system in an exemplary application environment.

FIG. 2 is a flow diagram of an embodiment of a diagnostic test method.

FIG. 3 is a block diagram of an embodiment of the diagnostic test system shown in FIG. 1.

FIG. 4 is a block diagram of an embodiment of the diagnostic test system shown in FIG. 3.

FIG. 5 is a block diagram of an embodiment of the diagnostic test system shown in FIG. 4.

FIG. 6 is a block diagram of an embodiment of the diagnostic test system shown in FIG. 3.

FIG. 7 is a block diagram of an embodiment of the diagnostic test system shown in FIG. 4.

FIG. 8 is a block diagram of an embodiment of the diagnostic test system shown in FIG. 4.

FIG. 9 is a block diagram of an embodiment of the diagnostic test system shown in FIG. 4.

### DETAILED DESCRIPTION

In the following description, like reference numbers are used to identify like elements. Furthermore, the drawings are intended to illustrate major features of exemplary embodiments in a diagrammatic manner. The drawings are not intended to depict every feature of actual embodiments nor relative dimensions of the depicted elements, and are not drawn to scale.

### I. Introduction

The embodiments that are described in detail below are capable of enabling a single user to easily determine the status of each of multiple point-of-care diagnostic tests that are being run concurrently. In this way, these embodiments enable the user to perform other tasks during the execution of multiple point-of-care tests, improving the efficient use of that person's time. In addition, these embodiments indicate the status of diagnostic tests in a manner that maintains the overall costs of diagnostic test systems below the price points needed for acceptance of these systems by the healthcare and insurance industries. Some of these embodiments are capable of indicating the status of point-of-care diagnostic systems and tests without displaying the results of the tests in a way that is perceptible by persons near the diagnostic test systems. This feature is particularly important for diagnostic testing applications, such as drug-of-abuse testing, where it is desirable to preserve the anonymity of persons being tested and to separate the reporting of the results from the testing location.

As used herein, the term “status” refers to a state of a diagnostic test system or a phase of a diagnostic test. The term “status” does not include the results of a diagnostic test.

The term “non-textual” means: not relating to or based on text.

The term “sensory” means: of or relating to sensation by a person or the senses of a person.

The term “perceptible” means: capable of being perceived by one or more of the senses of a person.

### II. Overview

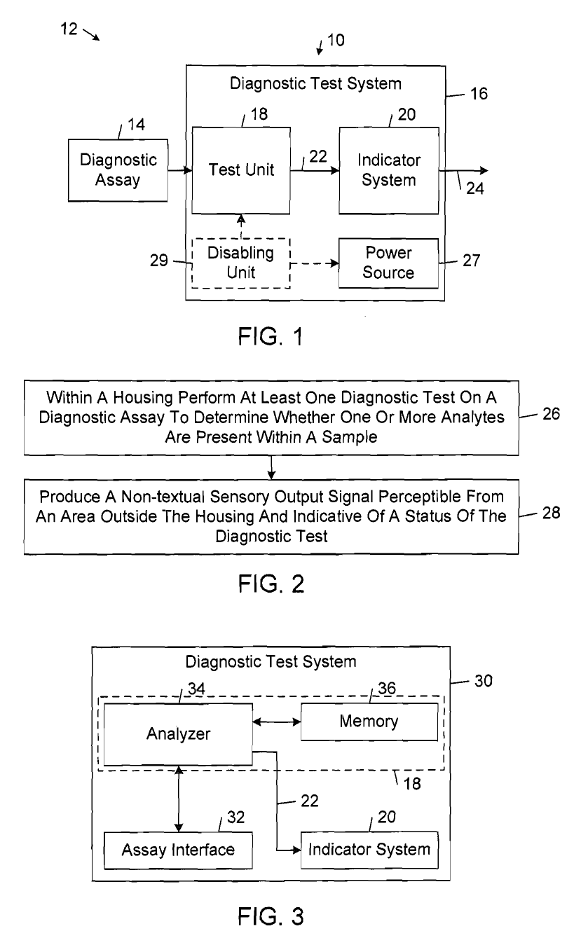

FIG. 1 shows an embodiment of a diagnostic test system 10 in an exemplary application environment 12 that includes a diagnostic assay 14. The diagnostic test system 10 includes a housing 16, a test unit 18, and an indicator system 20. In general, the diagnostic assay 14 may be any type of vehicle for assaying a wide variety of environmental samples (e.g., toxins and chemical contaminants) and physiological samples (e.g., urine, saliva, blood, and breath). Exemplary diagnostic assays include but are not limited to lateral flow assay test strips and ELIZAs (Enzyme Linked Immuno Sorbent Assays). The diagnostic test system 10 may be configured to perform any of a wide variety of different types of diagnostic tests on the diagnostic assay 14, including tests for any type of analyte, medical or environmental condition, or substance including but not limited to hormone, a metabolite, a toxin (e.g., a biotoxins), a pathogen-derived antigen, glucose, pregnancy, infectious diseases, cholesterol, cardiac markers, drugs-of-abuse, and chemical contaminants.

FIG. 2 shows an exemplary embodiment of a diagnostic test method that is implemented by the diagnostic test system 10. In accordance with this embodiment, within the housing 16, the test unit 18 performs at least one diagnostic test on the diagnostic assay 14 to determine whether at least one analyte is present within a sample in the diagnostic assay 14 (FIG. 2, block 26). The indicator system 20 produces the non-textual sensory output signal 24 that is perceptible from an area outside the housing 16 and is indicative of a status of the diagnostic test (FIG. 2, block 28).

Referring back to FIG. 1, the housing 16 may be made of any one of a wide variety of materials, including plastic and metal. The housing 16 typically has a size that allows it to be held by the user in one hand. The housing 16 protects or covers the test unit 18 and other components of the diagnostic test system 10. The indicator system 20 may be incorporated in the housing 16 or it may be affixed to an external surface of the housing 16. In some embodiments, the housing 16 defines a receptacle that mechanically registers the diagnostic assay 14 with respect to the test unit 18.

In general, the test unit 18 includes one or more electronic components for analyzing the diagnostic assay 14 to determine the presence of at least one analyte in the sample being assayed by the diagnostic assay 14. In some embodiments, the test unit 18 includes electronic components that measure one or more electrical properties (e.g., electrical resistance) of the sample in the diagnostic assay 14. In some embodiments, the test unit 18 includes one or more optoelectronic components that measure one or more optical properties of the sample in the diagnostic assay 14.

The test unit 18 also typically includes a control unit that analyzes the measurements to determine the presence of at least one target analyte in the sample. In general, the control unit may be implemented in any computing or processing environment, including in digital electronic circuitry or in computer hardware, firmware, or software. In some embodiments, the control unit is a microcontroller, a microprocessor, or an ASIC. In some embodiments, the control unit is incorporated within the housing 16 of the diagnostic test system 10. In other embodiments, the control unit is located in a separate device, such as a computer, that may communicate with the diagnostic test system 10 over a wired or wireless connection.

In some implementations, computer process instructions for implementing the methods that are executed by the test unit 18, as well as the data it generates, are stored in one or more machine-readable media. Machine-readable media suitable for tangibly embodying these instructions and data include all forms of computer-readable non-volatile memory, including, for example, semiconductor memory devices, such as EPROM, EEPROM, and flash memory devices, magnetic disks such as internal hard disks and removable hard disks, magneto-optical disks, DVD-ROM/RAM, and CD-ROM/RAM.

In general, the indicator system 20 may include any of a wide variety of different mechanisms for indicating the status of the diagnostic test system 10 or the status of a diagnostic assay test, including visual mechanisms, audio mechanisms, and vibrational mechanisms. In some implementations, the indicator system 20 includes one or more of an illumination system (e.g., one or more light-emitting diodes), an audio transducer, and a mechanical vibrator. The test unit 18 generates a status indicator control signal 22 that triggers the indicator system 20 to produce one or more non-textual sensory output signals 24 that indicate, for example, that the test unit is ready to perform a diagnostic test, that a diagnostic test is in progress, that a diagnostic test is complete (e.g., when a sufficient quantity of a labeling substance has accumulated in the control region of a lateral flow assay test strip). In some embodiments, the test unit 18 is free of any mechanism for controlling the indicator system 20 to indicate a result of a diagnostic test. This feature is particularly important for diagnostic testing applications, such as drug-of-abuse testing, where it is desirable to preserve the anonymity of persons being tested and to separate the reporting of the results from the testing location. These diagnostic test system embodiments typically are free of any mechanism that allows a user or other person to determine the test results at the point of care or point of collection. Instead, these embodiments typically include a communications interface that allows the diagnostic test system to transfer the test results to a host system over a wired or wireless connection.

In some embodiments, the diagnostic test system additionally includes an alphanumeric display (e.g., a two or three character light-emitting diode array) (not shown in FIG. 1) for presenting assay test results.

The diagnostic test system 16 typically includes a power source 27 (not shown in FIG. 1) that supplies power to the active components of the diagnostic test system 10, including the test unit 18 and the indicator system 20. The power source 27 may be implemented by, for example, a replaceable battery or a rechargeable battery.

Some embodiments of the diagnostic test system 10 optionally include a disabling unit 29 that is configured to disable the test unit 18 in response to a determination that the current lifetime of the test unit 18 has expired. The diagnostic test system 10 typically is free of any reset mechanism for re-enabling the test unit 18 after it has been disabled by the disabling unit 20. In this way, a user cannot easily re-enable the test unit 18 after its designated lifetime has expired.

The disabling unit 29 typically is configured to disable the test unit 18 before one or more operating characteristics of the test unit 18 are expected to fail to conform to a performance specification (or standard) that is associated with the test unit 18. For example, in some embodiments, the disabling unit 29 is configured to disable the test unit 18 before the precision, reliability, or sensitivity with which the test unit can perform one or more specified diagnostic tests falls below a specified level. In this regard, the disabling unit disables the test unit 18 in response to a determination that the current lifetime measure meets (e.g., is greater than or is at least equal to) an end-of-life threshold.

In some embodiments, the end-of-life threshold is a threshold value for the lifetime of the test unit 18 before which the test unit is expected to be able to perform reliably and with a particular sensitivity level. In general, the disabling unit 29 may include any of a wide variety of different mechanisms for determining the current lifetime of the test unit 18. For example, in some embodiments, the lifetime of the test unit 18 is measured as a continuous period or an aggregation of discrete operational (i.e., in-use) periods or a combination of both continuous and aggregated periods in other embodiments, the lifetime of the test unit 18 is measured by the number of times the test unit 18 performs a diagnostic test, as described in U.S. patent application Ser. No. 11/312,951, filed Dec. 19, 2005, by Patrick T. Petruno, and entitled “Diagnostic Test Reader with Disabling Unit.”

The disabling unit 20 may disable the test unit 18 in a wide variety of different ways. In some embodiments, the disabling unit 29 disables the test unit 160 by erasing or otherwise disabling at least a critical portion of a test program 166 that is needed by the test unit 18 to perform one or more diagnostic tests on the diagnostic assay 14. In some embodiments, the disabling unit 29 disables the test unit 18 by deleting at least a critical portion of the test information (e.g., initialization data or parameter values) that is needed by the test unit 18 to perform one or more diagnostic tests on the diagnostic assay 14. In some embodiments, the disabling unit 29 disables the test unit 18 by disconnecting the test unit 18 from a power source (e.g., an internal or external power supply). In some embodiments, the disabling unit 29 burns a fuse or activates some other permanent decoupling mechanism within test unit 18 in order to prevent use of test unit 18 to perform at least one diagnostic test on the diagnostic assay 14. The decoupling mechanism may be configured to: deprive the test unit 18 of power; disrupt communication between an assay interface that receives the diagnostic assay 14 and a processing module of the test unit 18; and/or disrupt communication between a processing module and a memory of the test unit 18.

In general, the disabling unit processing module may be implemented in any computing or processing environment, including in digital electronic circuitry or in computer hardware, firmware, or software. In some embodiments, the disabling unit processing module is a microcontroller, a microprocessor, or an ASIC. In some embodiments, the disabling unit processing module is incorporated within the housing 16 of the diagnostic test system 10. In other embodiments, the disabling unit processing module is located in a separate device, such as a computer, that may communicate with the diagnostic test system 10 over a wired or wireless connection.

### III. Exemplary Embodiments of the Diagnostic Test System

A. A First Exemplary Embodiment of the Diagnostic Test System

FIG. 3 shows an embodiment 30 of the diagnostic test system 10 that includes an assay interface 32 in addition to the indicator system 20 and the test unit 18. In this embodiment, the test unit 18 includes an analyzer 34 and a memory 36.

In some embodiments, the assay interface 32 is implemented by a port that receives a diagnostic assay, such as a lateral flow assay test strip. In other embodiments, the assay interface 32 is implemented by a coupling mechanism that enables the diagnostic test system 30 to be brought into the proximity of diagnostic assays, such as liquid form ELIZA assays that are performed in test tubes or micro-titer plates, or other assays in which handling might interrupt the function of the assay. In some embodiments, assay interface 32 couples with a sample container that contains the diagnostic assay 14, which includes a sample to be analyzed by the analyzer 34. In these embodiments, the diagnostic assay 14 may be, for example, a reservoir, a lateral flow assay test strip, or any other device that carries the sample.

The analyzer 34 measures one or more properties of the diagnostic assay 14 that is interfaced with the assay interface 32. The analyzer 34 analyzes the measurements to determine whether one or more target analytes are present in the sample carried by the diagnostic assay 14. In some embodiments, the analyzer 34 includes a control unit (not shown in FIG. 3) and a measurement system (not shown in FIG. 3) that detects the assay result. The measurement system may include, for example, one or more optoelectronic detectors (e.g., one or more photodiodes, a CCD imager, and a CMOS imagery. In addition to analyzing the measurements made by the measurement system, the control unit typically choreographs the operation of the diagnostic test system 30, including providing control mechanisms for timing and/or detection of start and stop times.

In some embodiments, the memory 36 stores a test program, which specifies a process that is executed by the control unit to determine one or more of the following: whether a target analyte is present in the sample; the quantity (e.g., concentration) of the target analyte is in the sample; and how the levels of the detected analyte relate to a particular ailment or condition. In general, the test program may include instructions for performing any method of analyzing a diagnostic test that depends on the presence or absence of at least one target analyte, including but not limited to any of the analytes described herein. For example, in some exemplary embodiments, the test program defines a process for optically analyzing a lateral flow assay test for a particular change in appearance (e.g., color) of a line in the assay test, wherein the change in appearance indicates the presence of a target analyte being tested for. In one embodiment in which diagnostic test system 10 executes a pregnancy test, the test program specifies a method for reviewing a lateral flow assay strip for a change of color indicating the presence of human chorionic gonadotropin (HCG) to determine whether or not a particular person is pregnant.

In general, a more precise and accurate result can be determined by using the analyzer 34 to analyze the diagnostic assay 14 as compared to manual reading of the assay. For example, in a typical pregnancy test, the degree of color change in an assay can vary greatly depending upon the level of HCG included in the blood or urine of the patient being tested. In early detection cases, the color change of the assay strip is relatively minor and may be undetectable to a user or may leave the user with questions regarding whether or not there was actually a color change in the assay strip. However, the analyzer 34 can more precisely analyze the degree of color change and determine a particular level of HCG within the assay. In this regard, a more definite and sensitive test result can be achieved.

B. A Second Exemplary Embodiment of the Diagnostic Test System

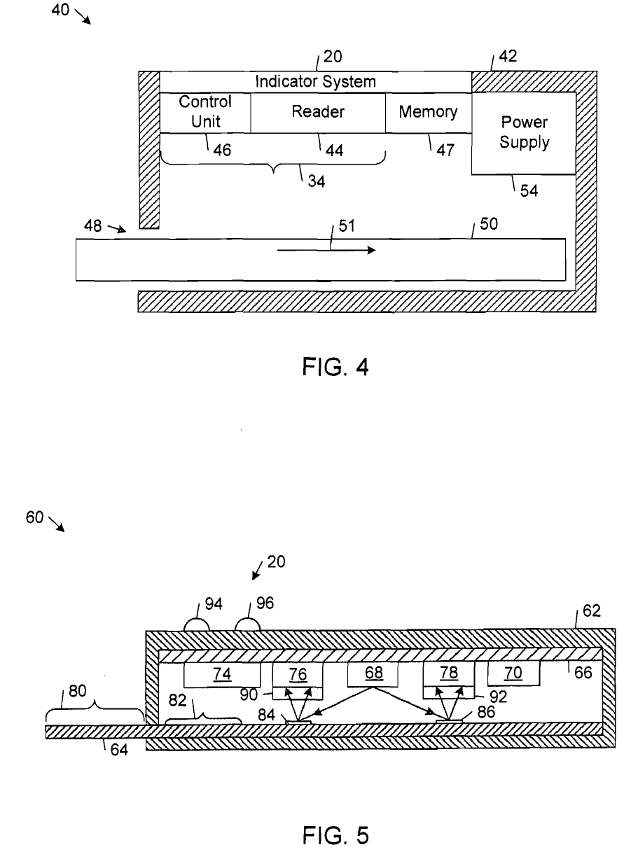

FIG. 4 is a block diagram of an embodiment 40 of the diagnostic test system 30 shown in FIG. 3. The diagnostic test system 40 includes a housing 42 and a memory 47 in addition to the indicator system 20 and the analyzer 34. In this embodiment, the analyzer 34 includes a reader 44 and a control unit 46. The housing 42 includes a port 48 for receiving a test strip 50. When the test strip 50 is loaded in the port 48, the reader 44 obtains light intensity measurements from the test strip 50. In general, the light intensity measurements may be unfiltered or they may be filtered in terms of at least one of wavelength and polarization. The control unit 46 computes at least one parameter from one or more of the light intensity measurements. In some implementations, the diagnostic test system 40 is fabricated from relatively inexpensive components enabling it to be used for disposable or single-use applications.

The housing 42 may be made of any one of a wide variety of materials, including plastic and metal. The housing 42 forms a protective enclosure for the reader 44, the control unit 46, the power supply 54, and other components of the diagnostic test system 40. The housing 42 also defines a receptacle that mechanically registers the test strip 50 with respect to the reader 44. The receptacle may be designed to receive any one of a wide variety of different types of test strips 50.

In general, the test strip 50 supports lateral flow of a fluid sample along a lateral flow direction 51. The test strip 50 typically includes a labeling zone containing a labeling substance that binds a label to a target analyte and a detection zone that includes at least one test region containing an immobilized substance that binds the target analyte. One or more areas of the detection zone, including at least a portion of the test region, are exposed for optical inspection by the reader 44. The exposed areas of the detection zone may or may not be covered by an optically transparent window.

The reader 44 includes one or more optoelectronic components for optically inspecting the exposed areas of the detection zone of the test strip 50. In some implementations, the reader 44 includes at least one light source and at least one light detector. In some implementations, the light source may include a semiconductor light-emitting diode and the light detector may include a semiconductor photodiode. Depending on the nature of the label that is used by the test strip 50, the light source may be designed to emit light within a particular wavelength range or light with a particular polarization. For example, if the label is a fluorescent label, such as a quantum dot, the light source would be designed to illuminate the exposed areas of the detection zone of the test strip 50 with light in a wavelength range that induces fluorescence from the label. Similarly, the light detector may be designed to selectively capture light from the exposed areas of the detection zone. For example, if the label is a fluorescent label, the light detector would be designed to selectively capture light within the wavelength range of the fluorescent light emitted by the label or with light of a particular polarization. On the other hand, if the label is a reflective-type label, the light detector would be designed to selectively capture light within the wavelength range of the light produced by the light source. To these ends, the light detector may include one or more optical filters that define the wavelength ranges or polarization axes of the captured light.

The control unit 46 processes the light intensity measurements that are obtained by the reader 44. In general, the control unit 46 may be implemented in any computing or processing environment, including in digital electronic circuitry or in computer hardware, firmware, or software. In some embodiments, the control unit 46 includes a processor (e.g., a microcontroller, a microprocessor, or ASIC) and an analog-to-digital converter. In the illustrated embodiment, the control unit 46 is incorporated within the housing 42 of the diagnostic test system 40. In other embodiments, the control unit 46 is located in a separate device, such as a computer, that may communicate with the diagnostic test system 40 over a wired or wireless connection.

In some embodiments, the control unit 46 is operable to generate the status indicator control signal 24 (see FIG. 1) in response to a determination that a diagnostic test is complete. For example, in some of these embodiments, the control unit 46 generates the status indicator control signal 24 in response to a determination that light intensity measured from a measurement region (e.g., a test region or a control region) on the lateral flow assay test strip 50 exceeds a threshold light intensity level.

A power supply 54 supplies power to the active components of the diagnostic test system 40, including the reader 44, the control unit 46, and the indicator system 20. The power supply 54 may be implemented by, for example, a replaceable battery or a rechargeable battery.

C. A Third Exemplary Embodiment of the Diagnostic Test System

FIG. 5 is a block diagram of an embodiment 60 of the diagnostic test system 40 shown in FIG. 4. The diagnostic test system 60 can test for any desired medical or environmental condition or substance including but not limited to any of the analytes described herein. The diagnostic test system 60 includes a housing 62, and a circuit 66 that includes a light source 68, a battery 70, a control unit 74, and photodetectors 76 and 78.

The housing 62 can be made of plastic or other material suitable for safely containing the liquid sample being analyzed. The housing is configured to contain at least a portion of a test strip 64. In the illustrated embodiment, housing 62 has an opening through which a portion of the test strip 64 extends for application of the sample to a sample receiving zone 80 of the test strip 64. In other embodiments, the test strip 64 is enclosed in the housing 62 during testing, and application of the sample to the test strip 64 is through an opening in the housing 62.

The test strip 64 typically is implemented by a lateral flow assay test strip. In some embodiments, the test strip 64 has a fluorescent substance for labeling the target analyte. Exemplary fluorescent substances include, but are not limited to, quantum dots or similar structures that fluoresce at a constant intensity when exposed to light of a specific wavelength, and fluorescent dye particles and rare earth particles that fluoresce with a decaying intensity over time.

To implement a test, a user applies a sample to sample receiving zone 80 of test strip 64. The sample flows from receiving zone 80 into a labeling zone 82 inside the housing 62. The labeling substance binds the quantum dot or other fluorescent structure to the target analyte. The sample including the labeling substance then enters a capture or detection zone that includes a test stripe 84 and a control stripe 86. The test stripe 84 is a region containing an immobilized substance selected to bind and retain the labeled complex containing the target analyte and the quantum dot. The control stripe 86 is a region containing an immobilized substance selected to bind to and retain to the labeling substance.

The light source 68 in circuit 66 illuminates the test stripe 84 and the control stripe 86 during testing. The light source 68 typically is a light emitting diode (LED) or a laser diode that emits light of a frequency that causes fluorescence of any quantum dots in the test stripe 84 or the control stripe 86. Generally, the quantum dots fluoresce under a high frequency (or short wavelength) light (e.g., blue to ultraviolet light) and the fluorescent light has a lower frequency (or a longer wavelength) than the light from light source 68.

The photodetectors 76 and 78 are in the respective paths of light emitted from the test stripe 84 and the control stripe 86 and measure the fluorescent light from the respective stripes 84 and 86. A baffle or other light directing structure (not shown) can be used to direct light from the test stripe 84 to the photodetector 76 and light from the control strip 86 to the photodetector 78. In the embodiment of FIG. 5, the photodetectors 76 and 78 have respective color filters 90 and 92 that transmit light of the frequency associated with the selected fluorescent light but block other frequencies, especially the frequency of light emitted from light source 68. Additionally, the labeling substance can include two types of quantum dots. One of the types of quantum dots emits a first wavelength of light and is attached to a substance that binds to the target analyte and to the test stripe 84. The other type of quantum dot emits light of a second wavelength and binds to the control stripe 86. The color filters 90 and 92 can then be designed so that photodetector 76 measures fluorescent light from the type of quantum dot that the test stripe 84 traps when the target analyte is present while photodetector 78 measures fluorescent light from the type of quantum dot that the control strip 86 traps.

The quantum dots provide fluorescent light at an intensity that is consistent for long periods of time, instead of rapidly degrading in the way that the intensity of conventional test dyes degrades when exposed to light. As a result, the intensity measurements from the detectors 76 and 78, which indicate the amount of fluorescent light, are proportional to the number of quantum dots in the respective stripes 84 and 86 and are not subject to rapid changes with time. These intensity measurements thus provide a quantitative indication of the concentration of the target analyte. The light intensity measurements of light fluorescing from fluorescent substances, such as fluorescent dyes and rare earth metals, on the other hand, are quantized based on knowledge of the exposure time and the characteristic fluorescent light intensity decay curves for these types of fluorescent substances.

The control unit 74, which can be a standard microcontroller or microprocessor with an analog-to-digital converter, receives electrical signals from the detectors 76 and 78. The electric signals indicate the measured intensities from stripes 84 and 86. The control unit 74 processes the electrical test signals and then operates an output system as required to indicate test results. In FIG. 5, for example, the output system includes LED lights 94 and 96. The control unit 74 can activate one light 94 when the fluorescent light from the test stripe 84 is above a threshold level marking the presence of the target analyte in test stripe 84. The control unit 74 can activate the other light 74 when the intensity of fluorescent light from the test stripe 84 is below the threshold level but the intensity that the photodetector 78 measures from the control stripe 86 is above a threshold level therefore indicating that the sample has passed through test stripe 84. A system with three or more LEDs or particular patterns of flashing of one or more LEDs can similarly indicate other test results (e.g., an inconclusive test) or a test status (e.g., to indicate a test in progress).

D. A Fourth Exemplary Embodiment of the Diagnostic Test System

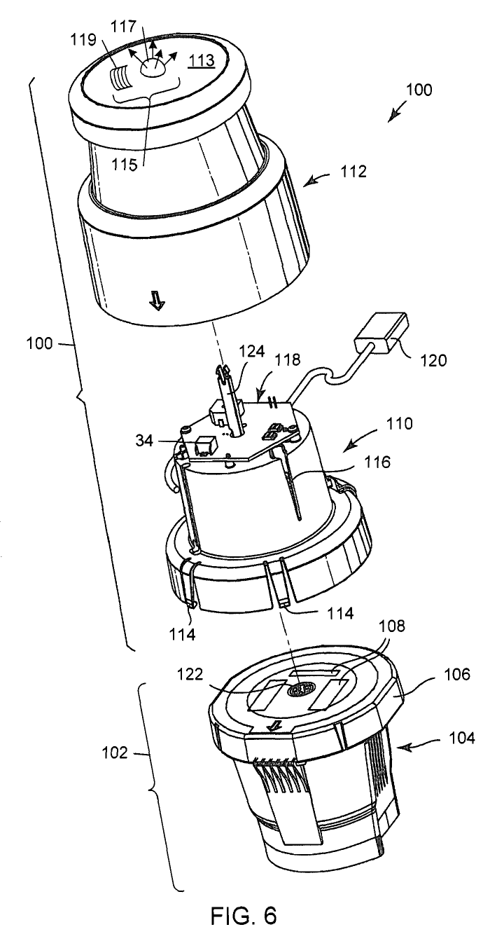

FIG. 6 is a block diagram of an embodiment 100 of the diagnostic test system 30 shown in FIG. 3 that is configured to analyze an embodiment 102 of the diagnostic assay 14 shown in FIG. 1.

The diagnostic assay 102 includes a sample collection cup 104 and a diagnostic lid 106. The sample collection cup 104 is configured to receive test fluids (e.g., urine or blood) from a patient. The lid 106 is configured to interface with an open end of the cup 104 to substantially enclose the sample fluid within the cup 104. In the illustrated embodiment, the lid 106 is substantially transparent to light produced by the analyzer 34. The lid 106 includes a plurality of lateral flow assay strips 108 that are generally visible through lid 106.

The diagnostic test system 100 interfaces with the lid 106 of the sample collection cup 104. The diagnostic test system is formed of two parts: an inner housing 110 and an outer housing 112. The outer housing 112 is configured to coaxially receive inner housing 110. The outer housing 112 includes a top surface 113 that supports an embodiment 115 of the indicator system 20 that includes a single light emitting diode 117 and an audio transducer 119. Circuitry 118 of the inner housing 110 is mounted to a top surface of the inner housing 110. In one example, the circuitry 118 includes the control unit 46, a timer, and an optoelectronic camera that is positioned within inner housing 110. The camera allows the diagnostic test system 100 to optically analyze the assay strips 108 in the lid 106. The inner housing 110 also includes a connector 120 that enables the control unit to communicate with a remote computer processing unit or other device. In one embodiment, the connector 120 is a universal serial bus (USB) connector.

In addition to analyzing the images captured by the camera, the control unit 46 produces status indicator control signals that trigger the light emitting diode 117 and the audio transducer to respectively produce visual and audio output signals indicating the status of a test. In some exemplary embodiments, the status indicator control signal directs the light emitting diode 117 to produce respective patterns of light flashes indicating that the diagnostic test system 100 is ready to perform a test, a diagnostic test is in progress, and a diagnostic test is complete. In some of these embodiments, the light emitting diode 117 produces a constant (non-flashing) light to indicate that the diagnostic test system 100 is ready to perform a test, a slowly flashing light to indicate that the diagnostic test system 100 is currently performing a test, and a rapidly flashing light to indicate that the diagnostic test system 100 has completed a test. In some exemplary embodiments, the status indicator control signal directs the audio transducer 119 to produce respective patterns of sound (e.g., beeps or tones) to indicate that the diagnostic test system 100 is ready to perform a test, a diagnostic test is in progress, and a diagnostic test is complete. The non-textual sensory output signals produced by the light emitting diode 117 and the audio transducer 119 may be redundant or complementary.

The diagnostic test system 100 is configured to be aligned with and pushed down at least partially over lid 106 to secure the diagnostic test system 100 to the lid 106. Upon coupling of the diagnostic test system 100 with the lid 106, the camera that is included in the circuitry 118 is positioned to optically capture images of the assay strips 108 through the lid 106. The inner housing 110 includes tabs 114 that are circumferentially spaced around an open periphery of the inner housing 110. The tabs 114 are bent toward the lid 106 during use to grasp the lid 106 and lock the diagnostic test system 100 to the lid 106. In one embodiment, bending or unbending of the tabs 114 may indicate to the diagnostic test system 100 that a test has been performed. In one example, springs 116 interact with the inner and outer housings 110 and 112 and facilitate decoupling of the diagnostic test system 100 with the lid 106.

In the illustrated embodiment, the lid 106 includes a cavity 122 that has an aliquot plunger, and the diagnostic test system 100 includes an index member 124. After the inner housing 110 is positioned on the lid 106, the outer housing 112 is pushed toward the inner housing 110, thereby, moving the index member 124 down into the cavity 122. The index member 124 interacts with the aliquot plunger causing sample fluid in the cup 104 to be aliquot to the assays 108.

In operation, once the inner housing 1 10 grasps the lid 106, the timer begins a countdown of the predetermined time period required to complete the analysis of the assay strips 108 in the lid 106. The optoelectronic camera in the inner housing 110 views the assays 108 through the transparent lid 106 to determine whether or not a particular analyte is present by analyzing any color change of the test trip 108. At the end of the predetermined time period, if no analyte is detected, then the test is negative. Regardless of whether or not the analyte was detected, the test typically is complete upon the expiration of the predetermined time period. Therefore, in one embodiment, the expiration of the time period serves as an end-of-test trigger.

### IV. Exemplary Embodiments of the Indicator System

A. Overview

As explained above, the indicator system 20 may include one or more mechanisms for indicating the status of the diagnostic test system 10 or a diagnostic assay test, including but not limited to visual mechanisms, audio mechanisms, and vibrational mechanisms. In the embodiments described herein, the indicator system 20 produces non-textual sensory output signals in response to a status indicator control signal 22 that is produced by the test unit 18. In some embodiments, the status indicator control signal 22 contains control codes that control the production of the non-textual sensory output signal by the status indicator system 20. The particular control code that is conveyed by the status indicator control signal 22 depends on the results of a status determination that is made by the test unit 18. Each of the different status determination results is associated with a different respective control code, and each of the different control codes is associated with the production of a different respective non-textual sensory output signal by the indicator system 20.

A mapping between an exemplary set of results of status determinations that are made by the test unit 18 and an exemplary set of non-textual sensory output signals that are produced by the status indicator system 20 is contained in Table 1.

TABLE 1

| | Non-Textual Sensory Output |
|---|---|
| | Signal Produced by Status |
| Status Determination Result | Indicator System |
| Test Unit is Calibrating System | Sensory Output Signal |
| | Indicating a “Calibration” State |
| Test Unit is Ready to Perform a | Sensory Output Signal |
| Diagnostic Assay Test | Indicating a “Ready” State |
| Test Unit Currently is | Sensory Output Signal |
| Performing a Diagnostic Assay | Indicating a “Test-In-Progress” |
| Test | State |
| Test Unit has Completed a | Sensory Output Signal |
| Diagnostic Assay Test | Indicating an “End-of-Test” |
| | State |

The different non-textual sensory output signals that are produced by the status indicator system correspond to different respective patterns of visual, audio, and/or vibrational signals. For example, in embodiments of the diagnostic test system 100 (see FIG. 6), the status indicator control signal controls the light emitting diode 117 to produce a constant (non-flashing) light to indicate that the diagnostic test system 100 is ready to perform a test, a slowly flashing light to indicate that the diagnostic test system 100 is currently performing a test, and a rapidly flashing light to indicate that the diagnostic test system 100 has complete a test. The status indicator control signal also directs the audio transducer 119 to produce respective patterns of sounds (e.g., beeps or tones) that indicate information about the status of the diagnostic test system 100 or the status of a diagnostic assay test that is redundant or complementary to the information conveyed by the light emitting diode 117.

B. Exemplary Visual Indicator System Embodiments

In general, visual indicator systems include any type of light source that produces a non-textual visual output signal that is perceptible from an area outside the housing of the diagnostic test system. Exemplary light sources include but are not limited to light emitting diodes, semiconductor lasers, and incandescent bulbs.

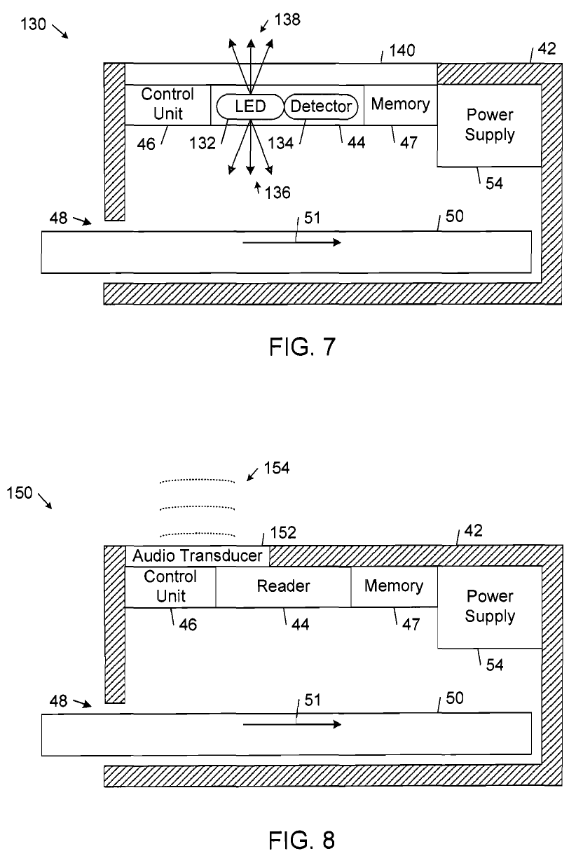

FIG. 7 is a block diagram of an embodiment 130 of the diagnostic test system 40 shown in FIG. 4. In this embodiment, the reader 44 includes a light emitting diode 132 and a photodetector 134.

During a diagnostic assay test, the light emitting diode 132 produces light 136 that illuminates regions of the test strip 50, the photodetector 134 produces electrical measurement signals in response to the intensity of light received from the illuminated regions of the test strip 50, and the control unit 46 analyzes the measurement signals to determine whether one or more target analytes are present in the sample being assayed by the test strip 50.

The light emitting diode 132 also produces light 138 in response to the status indicator control signal that is generated by the control unit 46. The status indicator control signal causes the light emitting diode 132 to produce the light 138 in a pattern that indicates the result of a status determination that is made by the control unit 46. At least a portion 140 of the housing is translucent of the light 138, enabling the light 138 to be perceived from an area outside the housing 42. In some embodiments, the translucent housing portion 140 forms a transparent window that minimally interferes with the transmission of the light 138 to the area outside of the housing 42. In other embodiments, the translucent portion 140 is formed of a material (e.g., plastic) that diffusely transmits the light 138 in a way that makes the housing 42 appear to be glowing when the light 138 is produced by the light emitting diode 132.

C. Exemplary Audio Indicator System Embodiments

In general, audio indicator systems include any type of audio source that produces an audio output signal that is perceptible from an area outside the housing of the diagnostic test system. Exemplary audio sources include but are not limited to speakers, such as piezoelectric speakers that produce beeps and tones.

FIG. 8 is a block diagram of an embodiment 150 of the diagnostic test system 40 shown in FIG. 4 that includes an audio transducer 152. The audio transducer 152 produces sound 154 in response to the status indicator control signal that is generated by the control unit 46. The status indicator control signal causes the audio transducer 152 to produce the sound 154 in a pattern that indicates the result of a status determination that is made by the control unit 46. The audio transducer 152 typically is located near an external surface of the housing 42 to enable the sound 154 to be perceived from an area outside the housing 42.

D. Exemplary Vibrational Indicator System Embodiments

In general, vibrational indicator systems include any type of vibration source that produces a mechanical vibrational output signal that is perceptible from an area outside the housing of the diagnostic test system. Exemplary vibration sources include but are not limited to piezoelectric vibrators and electric motor based vibrators of the types described in U.S. Pat. No. 6,281,785.

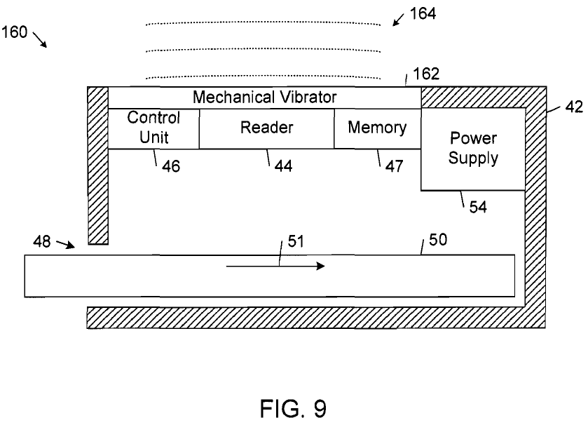

FIG. 9 is a block diagram of an embodiment 160 of the diagnostic test system 40 shown in FIG. 4 that includes a mechanical vibrator 162. The mechanical vibrator 162 produces vibrations 164 in response to the status indicator control signal that is generated by the control unit 46. The status indicator control signal causes the mechanical vibrator 162 to produce the vibrations 164 in a pattern that indicates the result of a status determination that is made by the control unit 46. The mechanical vibrator 162 typically is located near an external surface of the housing 42 to enable the vibrations 162 to be perceived from an area outside the housing 42.

### V. Conclusion

The embodiments that are described in detail herein are capable of enabling a single user to easily determine the status of each of multiple point-of-care diagnostic tests that are being run concurrently. In this way, these embodiments enable the user to perform other tasks during the execution of multiple point-of-care tests, improving the efficient use of that person's time. In addition, these embodiments indicate the status of diagnostic tests in a manner that maintains the overall costs of diagnostic test systems below the price points needed for acceptance of these systems by the healthcare and insurance industries. Some of these embodiments are capable of indicating the status of point-of-care diagnostic systems and tests without displaying the results of the tests in a way that is perceptible by persons near the diagnostic test systems.

Other embodiments are within the scope of the claims.

What is claimed is:

1. A diagnostic test system, comprising:
a housing;
an indicator system operable to produce a non-textual sensory output signal perceptible from an area outside the housing; and
a test unit in the housing operable to perform at least one diagnostic test on a diagnostic assay to determine whether at least one analyte is present within a sample and to produce a status indicator control signal triggering the indicator system to indicate a status of the diagnostic test via the non-textual sensory output signal.

2. The diagnostic test system of claim 1, further comprising a light emitting diode operable to produce light in response to the status indicator control signal.

3. The diagnostic test system of claim 2, wherein the light emitting diode is located on an external surface of the housing.

4. The diagnostic test system of claim 2, wherein the light emitting diode produces the non-textual sensory output signal and produces light that illuminates the sample during at least a portion of the diagnostic test.

5. The diagnostic test system of claim 2, wherein the housing contains the test unit and the light emitting diode, at least a portion of the housing is translucent, and the non-textual sensory output signal corresponds to light produced by the light emitting diode and output through the translucent portion of the housing.

6. The diagnostic test system of claim 2, wherein the test unit also is operable to produce a test control signal triggering the light emitting diode to illuminate the sample during at least a portion of the diagnostic test.

7. The diagnostic test system of claim 2, further comprising at least one additional light emitting diodes each operable to produce light in response to the status indicator control signal.

8. The diagnostic test system of claim 1, further comprising an audio transducer operable to produce an audible signal in response to the status indicator control signal.

9. The diagnostic test system of claim 1, further comprising a mechanical vibrator operable to produce a vibrational signal in response to the status indicator control signal.

10. The diagnostic test system of claim 1, wherein the test unit is operable to generate status indicator control signal in response to a determination that the diagnostic test is complete.

11. The diagnostic test system of claim 10, wherein the test unit generates the status indicator control signal in response to a determination that light intensity measured from a measurement region of a lateral flow assay test strip exceeds a threshold light intensity level.

12. The diagnostic test system of claim 1, wherein the test unit is operable to generate the status indicator control signal in response to a determination that the diagnostic test is in progress.

13. The diagnostic test system of claim 1, wherein the test unit is operable to generate the status indicator control signal in response to a determination that the test unit is ready to perform the diagnostic test.

14. The diagnostic test system of claim 1, wherein:
the housing comprises an interface that receives a diagnostic assay test strip that supports lateral flow of a fluid sample, includes a labeling zone containing ones or more labeling substances that bind labels to the one or more analytes, and includes a detection zone comprising at least one test region containing an immobilized substance that binds the one or more analytes, wherein the detection zone includes an area that is exposed for optical inspection; and
the test unit comprises a reader configured to obtain light intensity measurements from the exposed area of the detection zone when the diagnostic assay test strip is loaded in the interface.

15. The diagnostic test system of claim 1, further comprising a disabling unit that is configured to disable the test unit in response to a determination that the current lifetime of the test unit has expired.

16. The diagnostic test system of claim 1, wherein the test unit is free of any mechanism for controlling the indicator system to indicate a result of the diagnostic test.

17. A diagnostic test system, comprising:
housing means;
indicator means for producing a non-textual sensory output signal perceptible from an area outside the housing; and
in the housing means, test unit means for performing at least one diagnostic test on a diagnostic assay to determine whether at least one analyte is present within a sample and for producing status indicator control signal means for triggering the indicator system to indicate a status of the diagnostic test via the non-textual sensory output signal.

18. A diagnostic test method, comprising:
within a housing performing at least one diagnostic test on a diagnostic assay to determine whether at least one analyte is present within a sample; and
producing a non-textual sensory output signal perceptible from an area outside the housing and indicative of a status of the diagnostic test.

19. The diagnostic test method of claim 18, wherein the producing comprises generating the non-textual sensory output signal in response to a determination that the diagnostic test is complete.

20. The diagnostic test method of claim 19, wherein the producing comprises generating the non-textual sensory output signal in response to a determination that light intensity measured from a measurement region of a lateral flow assay test strip exceeds a threshold light intensity level.

21. The diagnostic test method of claim 18, wherein the producing comprises generating the non-textual sensory output signal in response to at least one of a determination that the diagnostic test is in progress and a determination that the test unit is ready to perform the diagnostic test.

22. The diagnostic test method of claim 18, wherein the producing comprises operating a light emitting diode to produce the non-textual sensory output signal from, and further comprising operating the light emitting diode to produce light that illuminates the sample during at least a portion of the diagnostic test.
